(19) United States
(12) Patent Application Publication
(10) Pub. No.: US 2015/0179867 A1
(43) Pub. Date: Jun. 25, 2015

(54) METHOD FOR MANUFACTURING PHOTOELECTRIC CONVERSION DEVICE

(71) Applicant: CANON KABUSHIKI KAISHA, Tokyo (JP)

(72) Inventors: Tetsuya Kimura, Fuchu-shi (JP); Takayasu Kanesada, Yamato-shi (JP); Toru Eto, Oita-shi (JP); Takaharu Kondo, Yokohama-shi (JP)

(21) Appl. No.: 14/579,171

(22) Filed: Dec. 22, 2014

(30) Foreign Application Priority Data
Dec. 25, 2013 (JP) 2013-267145

(51) Int. Cl. H01L 31/18; H01L 31/0232

(52) U.S. Cl. CPC H01L 31/18; H01L 31/02327

(57) ABSTRACT

In a method for manufacturing a photoelectric conversion device which includes: a substrate including a photoelectric conversion element; and a light guide which includes an insulator having an opening corresponding to the photoelectric conversion element and containing silicon oxide and a member located in the opening and containing silicon nitride, the method includes: forming a first silicon nitride film which forms the member in the opening by a parallel plate type plasma CVD apparatus; and forming a second silicon nitride film which forms the member in the opening and on the first silicon nitride film by a high density plasma CVD apparatus. In the photoelectric conversion device, the first silicon nitride film has a thickness of 55 nm or more.

### BACKGROUND OF THE INVENTION

1. Field of the Invention

The present invention relates to a method for manufacturing a photoelectric conversion device.

2. Description of the Related Art

In recent years, in order to increase the quantity of light incident on a photoelectric conversion element, a photoelectric conversion device including a light guide has been proposed. In order to form a light guide, Japanese Patent Laid-Open No. 2012-182431 has disclosed a method to fill a film having a high refractive index in an opening of an insulator.

### SUMMARY OF THE INVENTION

The present invention provides a method for manufacturing a photoelectric conversion device which includes: a substrate including a photoelectric conversion element; and a light guide. The light guides includes an insulator which is provided on the substrate, has an opening corresponding to the photoelectric conversion element, and contains silicon oxide, and a member which is provided on the substrate, is located in the opening, and contains silicon nitride. The method described above comprises: forming a first silicon nitride film which forms the member in the opening using a parallel plate type plasma chemical vapor deposition (CVD) apparatus; and forming a second silicon nitride film which forms the member in the opening and also on the first silicon nitride film using a high density plasma CVD apparatus. In this method, the first silicon nitride film has a thickness of 55 nm or more.

Further features of the present invention will become apparent from the following description of exemplary embodiments with reference to the attached drawings.

### BRIEF DESCRIPTION OF THE DRAWINGS

FIG. 1 is a schematic cross-section view illustrating the structure of a photoelectric conversion device according to a first embodiment.

FIGS. 2A to 2C are each a schematic cross-section view illustrating a method for manufacturing the photoelectric conversion device according to the first embodiment.

FIGS. 3A and 3B are each a schematic cross-section view illustrating the method for manufacturing the photoelectric conversion device according to the first embodiment.

FIG. 4A is a schematic cross-section view illustrating the structure of a manufacturing apparatus.

FIG. 4B is a schematic cross-section view illustrating the structure of another manufacturing apparatus.

FIGS. 5A and 5B are each a graph showing the relationship between the number of defects and the film thickness according to the first embodiment.

FIG. 6 is a graph showing the analytical result according to the first embodiment.

FIG. 7 is a schematic cross-sectional view illustrating the structure of a photoelectric conversion device according to a third embodiment.

### DESCRIPTION OF THE EMBODIMENTS

The present inventors found that in the method disclosed in Japanese Patent Laid-Open No. 2012-182431, the film formed inside the opening may be peeled away from the insulator or may be peeled away together with a part of the insulator in some cases. By the phenomenon described above, the yield of the photoelectric conversion device including a light guide is decreased.

The present invention provides a method for manufacturing a photoelectric conversion device including a light guide which can improve the yield of the photoelectric conversion device.

Hereinafter, embodiments of the present invention will be described using a CMOS type photoelectric conversion device as the photoelectric conversion device by way of example. However, the present invention is not limited to the structures of the embodiments. For example, the embodiments may be appropriately used in combination and may be appropriately changed and/or modified within the scope of the present invention. Furthermore, the photoelectric conversion device is not limited to a CMOS type structure and may have another structure. As materials forming the photoelectric conversion device, main materials thereof are described below by way of example, and elements, such as oxygen and/or nitrogen, may also be appropriately contained.

### First Embodiment

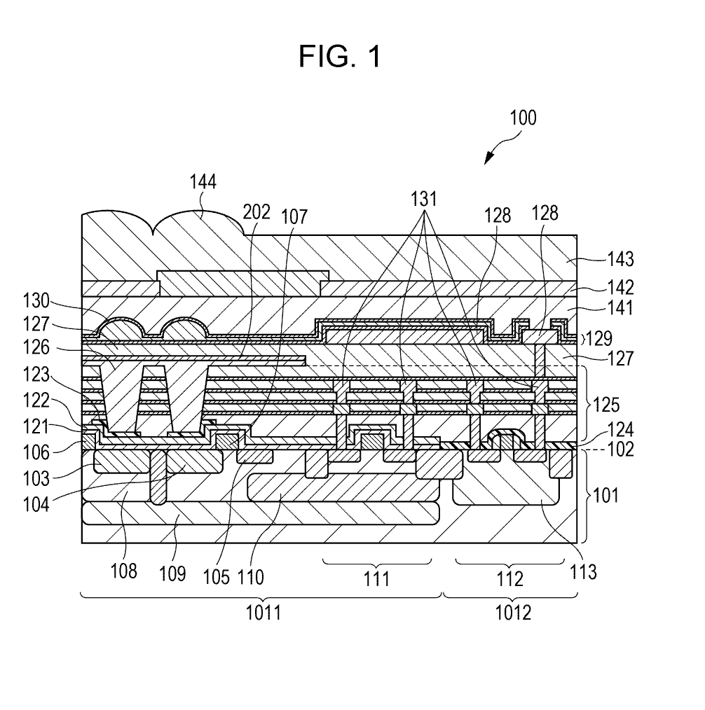

A first embodiment will be described with reference to FIGS. 1 to 6. First, with reference to FIG. 1, a photoelectric conversion device according to this embodiment will be described.

FIG. 1 is a schematic cross-section view showing an important portion of a photoelectric conversion device 100 according to this embodiment. In particular, in FIG. 1, an image pickup region 1011 and a peripheral region 1012 of the photoelectric conversion device 100 are shown. In the image pickup region 1011, a plurality of photoelectric conversion elements are provided, and in the peripheral region 1012, circuits for reading and processing of signals from the photoelectric conversion elements are provided. The photoelectric conversion device 100 includes a semiconductor substrate 101 having a primary surface 102. A material of the semiconductor substrate 101 is, for example, silicon.

In the image pickup region 1011 of the semiconductor substrate 101, two N-type semiconductor regions 103 and 104 are provided. The two N-type semiconductor regions 103 and 104 are each able to function as a charge storage region of each photoelectric conversion element. In addition, in the image pickup region 1011 of the semiconductor substrate 101, N-type semiconductor regions 105 and gate electrodes 106 and 107 are provided. The N-type semiconductor region 105 is also called a floating diffusion region (hereinafter referred to as the “FD region 105”). The gate electrodes 106 and 107 each function as the gate electrode of a transfer transistor. The gate electrode 107 transfers a signal charge from the N-type semiconductor region 104 to the FD region 105. Furthermore, in the image pickup region 1011 of the semiconductor substrate 101, a transistor 111 is provided. The transistor 111 is a transistor, such as a reset transistor or an amplification transistor, which is included in a pixel. In this case, the transistor 111 is an N-type MOS transistor and has the gate electrode and the source and the drain regions, each of which is an N-type semiconductor region. In addition, in the image pickup region 1011, an N-type semiconductor region 108 and P-type semiconductor regions 109 and 110 are provided. The N-type semiconductor region 108 has a lower impurity concentration than that of the N-type semiconductor region 104 and forms a part of the photoelectric conversion element. The P-type semiconductor region 109 is located under the N-type semiconductor region 108 and forms a part of the photoelectric conversion element. The P-type semiconductor region 110 is located under the transistor 111 and the FD region 105.

In the peripheral region 1012 of the semiconductor substrate 101, transistors forming a CMOS circuit are disposed. In FIG. 1, a transistor 112, which is an N-type transistor, is only shown. The transistor 112 has the gate electrode and the N-type source and drain regions, which are disposed in a P-type semiconductor region 113.

In the image pickup region 1011 on the semiconductor substrate 101, a silicon nitride film 121 is provided so as to cover the semiconductor regions and the gate electrodes, and on the film 121, a silicon oxide film 122 is provided. Furthermore, silicon nitride films 123 are provided on the film 122 so as to correspond to the N-type semiconductor regions 103 and 104. In this structure, between the semiconductor substrate 101 in the image pickup region 1011 and the silicon nitride film 121, a silicon oxide film (not shown) also functioning as a gate oxide film may be provide. In the peripheral region 1012 on the semiconductor substrate 101, a silicon nitride film 124 covering the gate electrode of the transistor 112 is provided. The gate electrode of the transistor 112 is provided with side spacers. In addition, an insulator 125 is provided over the image pickup region 1011 and the peripheral region 1012 so as to cover the films 122, 123, and 124. Although primarily formed of silicon oxide films, the insulator 125 may also include a silicon nitride film, a silicon oxynitride film, a silicon carbide film, and the like. The insulator 125 of this embodiment includes silicon oxide films and silicon nitride insulating films, which are alternately laminated to each other. The silicon oxide films are each formed to have a thickness of 120 to 1,000 nm by a plasma chemical vapor deposition (hereinafter referred to as “CVD”) method. The silicon nitride films are each formed to have a thickness of 10 to 200 nm by a plasma CVD method. In this embodiment, the thickness of each silicon oxide film is set to be larger than that of each silicon nitride film. A member 126 which will be described later may have a high refractive index as compared to that of a film having the lowest refractive index of this insulator 125. Alternatively, the insulator 125 may be formed from a single component film. In addition, in the insulator 125, conductors 131 are provided. The conductor 131 includes a contact plug containing copper or tungsten as a primary component or a wiring layer containing copper or aluminum as a primary component.

The insulator 125 has openings corresponding to the N-type semiconductor regions 103 and 104. The member 126 is provided in each opening. The member 126 contains silicon nitride which is a material having a refractive index higher than that of the layer of the insulator 125. The member 126 may be a material which forms the interface with the layer of the insulator 125 and which reflects incident light. The insulator 125 and the member 126 collectively form a light guide. On the insulator 125, a silicon oxide film 127 is provided, and on the film 127, a wiring layer 128 functioning as a light shielding film and a film 129 covering the wiring layer 128 are provided. The film 129 includes a silicon nitride film and is able to function as a protective film. In addition, the film 129 has a convex portion 130, and the convex portion 130 functions as an interlayer lens. On the film 129, for example, an organic material film 141, a color filter layer 142 including a plurality of color filters, and a microlens layer 143 including microlenses 144 are provided.

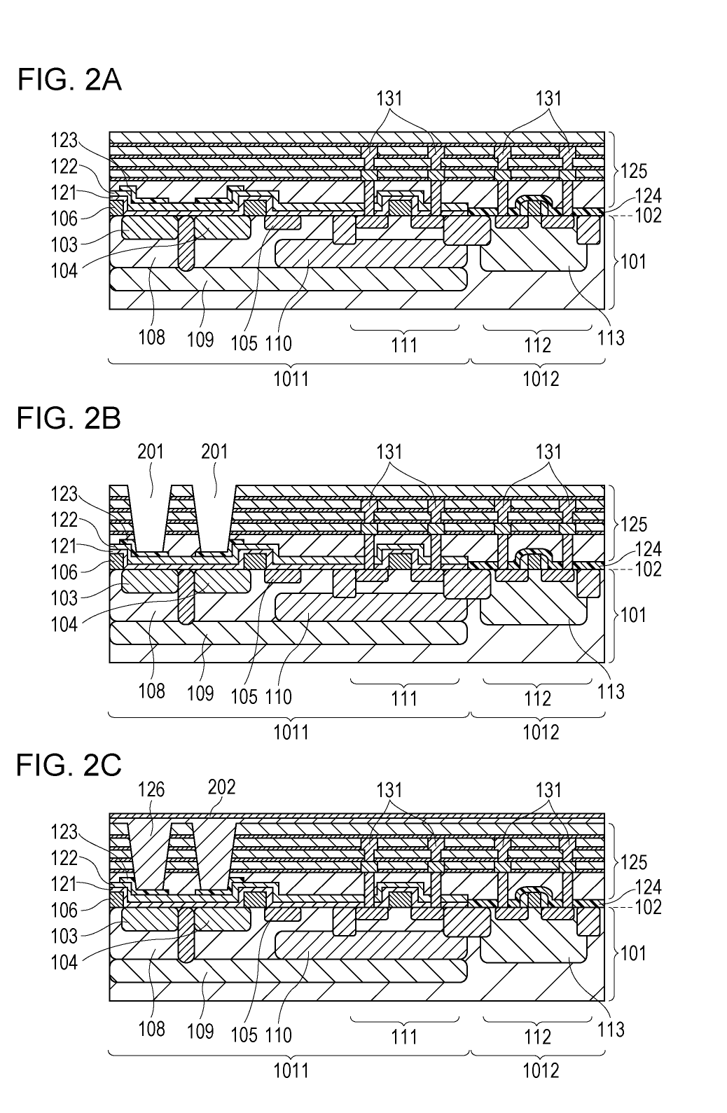

Next, a method for manufacturing a photoelectric conversion device according to this embodiment will be described with reference to FIGS. 2A to 2C. FIGS. 2A to 2C are each a schematic cross-section view of a photoelectric conversion device and each show a photoelectric conversion device at an arbitrary stage of the manufacturing method. In FIGS. 2A to 2C, constituent elements corresponding to those shown in FIG. 1 are designated by the same reference numerals as those in FIG. 1, and description thereof will be omitted. In addition, in FIGS. 2A to 2C, a constituent element before processing and a constituent element after processing are designated by the same reference numeral.

In FIG. 2A, the semiconductor substrate 101 is prepared. In the semiconductor substrate 101, elements, such as photoelectric conversion elements and transistors, are formed. Those elements can be formed using a general semiconductor technique, and description thereof will be omitted. On the semiconductor substrate 101, the films 121 to 124 are formed. Those films can be formed by a plasma CVD method. Furthermore, on the semiconductor substrate 101, the conductors 131 are provided, and the insulator 125 insulates the conductors 131 from each other.

Next, as shown in FIG. 2B, the openings 201 are formed in the insulator 125. The openings 201 are formed so as to correspond to the respective photoelectric conversion elements. In this case, the openings 201 are each provided so as to correspond to each of the N-type semiconductor regions 103 and 104. The opening 201 can be formed using a photolithographic technique and an etching technique. In this step, the film 123 may function as an etching stopper film when the opening 201 is formed.

Next, as shown in FIG. 2C, the member 126 containing silicon nitride is formed in the opening 201 of the insulator 125. The member 126 is formed by depositing a silicone nitride film using a plasma CVD method. A method for manufacturing this member 126 will be described later in detail. The silicon nitride film is formed so as to fill the opening 201 and cover the upper surface of the insulator 125. Subsequently, the silicon nitride film is processed by a planarization treatment using at least one of an etching technique and a chemical mechanical polishing (hereinafter referred to as “CMP”) technique, so that the upper surface of the film is planarized. For example, since the member 126 thus processed remains on the upper surface of the insulator 125 to have a thickness of approximately 100 to 500 nm, the member 126 is able to function as a protective film. Furthermore, after the planarization treatment is performed, a silicon oxynitride film 202 is formed on the member 126.

Subsequently, as shown in FIG. 1, the member 126 located in the peripheral region 1012 is removed, the film 127 is formed, and via plugs and the wiring layer 128 are formed. After the wiring layer 128 is formed, the film 129 is formed. In this case, the film 129 has a three-layer structure including a silicon oxynitride, a silicon nitride, and a silicon oxynitride layer. In addition, on the film 129, the film 141 which can be planarized is formed from an organic material, and the color filter layer 142 and the microlens layer 143 are then sequentially formed. Those layers can be formed by a method for manufacturing a general photoelectric conversion device. As described above, the photoelectric conversion device shown in FIG. 1 is formed.

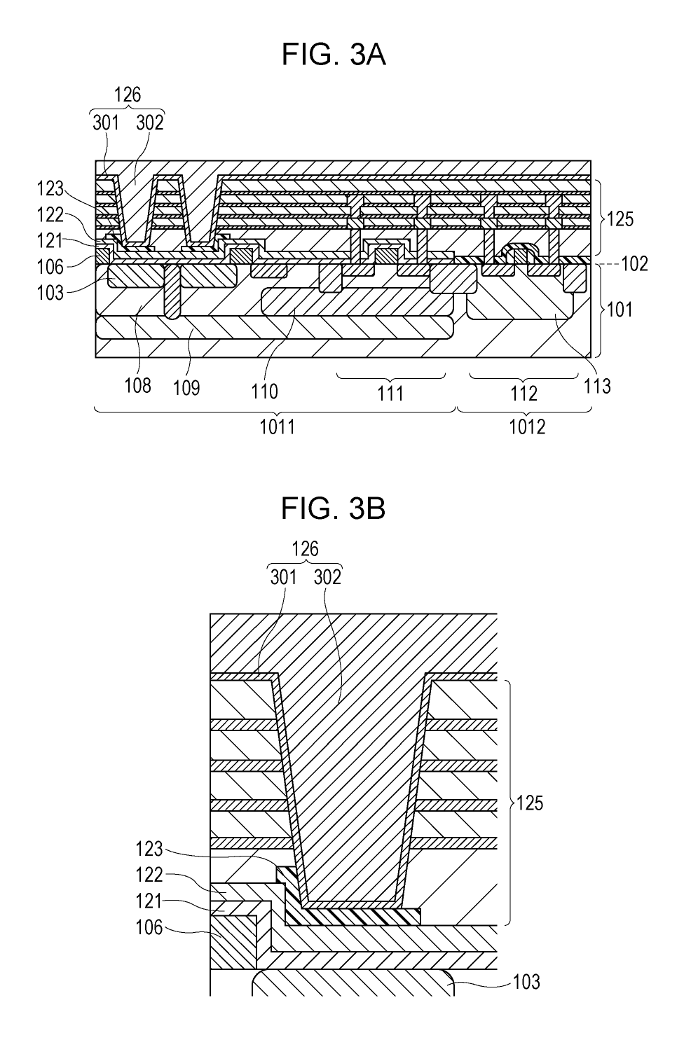

Next, a method for forming the member 126 containing silicon nitride described above will be described in detail with reference to FIGS. 3A to 5B. In this embodiment, the silicon nitride film which forms the member 126 is formed by a two-step process. FIG. 3A is a schematic cross-section view of a photoelectric conversion device corresponding to that shown in FIG. 2C, and FIG. 3B is a partially enlarged schematic cross-section view of the photoelectric conversion device shown in FIG. 3A. As shown in FIG. 3A, the member 126 includes two films 301 and 302. In FIG. 3A, the film 301 is formed along the side wall of the opening 201 and covers the upper surface of the insulator 125. In addition, after the film 302 is formed so as to cover the film 301 and fill the opening 201, the planarization treatment is performed. Next, a particular manufacturing method will be described.

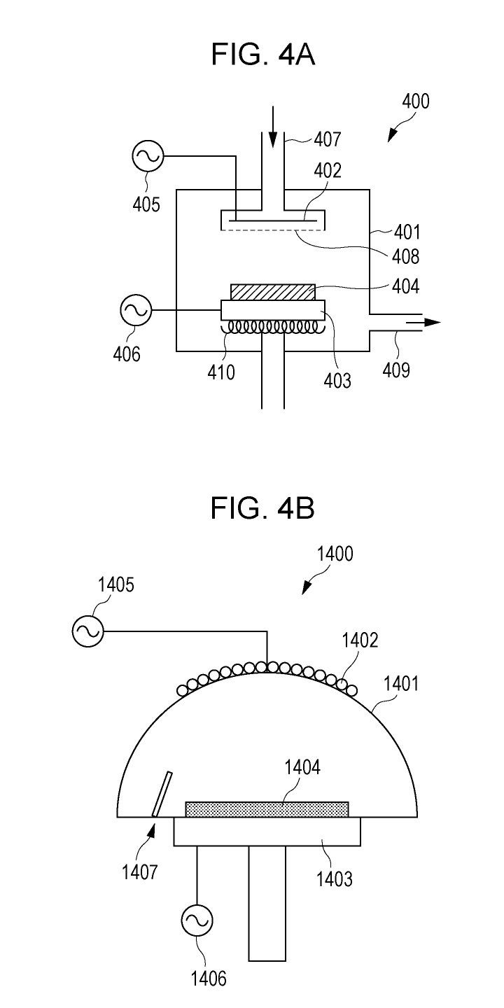

First, after the openings 201 are formed as shown in FIG. 2B, the silicon nitride film 301 (first film) is formed using a parallel plate type plasma CVD apparatus (first step). FIG. 4A shows a parallel plate type plasma CVD apparatus 400. The parallel plate type plasma CVD apparatus 400 has a chamber 401, an upper electrode 402, and a lower electrode 403. The upper electrode 402 and the lower electrode 403 face each other. In addition, the lower electrode 403 also functions as a stage, and a semiconductor substrate 404 can be placed thereon. In addition, the upper electrode 402 is connected to a high-frequency generator 405, and the lower electrode 403 is connected to a high-frequency generator 406. A reaction gas is supplied from a supply port 407 to the stage through a dispersion plate 408 and is then discharged from an outlet port 409. In addition, the temperature of the semiconductor substrate 404 is set to a predetermined temperature by a heater 410.

In the parallel plate type plasma CVD apparatus 400 as described above, the film formation conditions are set as follows. First, by the high-frequency generator 405, an electrical power (high frequency power) of 600 to 1,000 W at an output frequency of 13.56 MHz is supplied to the upper electrode 402. In addition, by the high-frequency generator 406, an electrical power (high frequency power) of 1,000 W or less at an output frequency of 13.56 MHz is supplied to the lower electrode 403. In this case, the electrical power may not be supplied to the lower electrode 403 from the high-frequency generator 406. In this embodiment, an electrical power of 800 W is supplied to the upper electrode 402, and an electrical power of 0 W is supplied to the lower electrode 403, that is, the electrical power is not supplied thereto. In this case, the potential of the lower electrode 403 is grounded. In addition, into the parallel plate type plasma CVD apparatus 400, a silicon-containing gas, nitrogen, and a nitrogen-containing gas are supplied from the supply port 407 as raw material gases. Incidentally, the silicon-containing gas indicates silane, tetraethoxysilane (TEOS), trimethylsilane, tetramethylsilane, or the like, and the nitrogen-containing gas indicates ammonia, N₂, or the like. In this embodiment, silane, nitrogen, and a gas containing ammonia are used. Under the conditions as described above, the film 301 is formed.

Next, by the use of a high density plasma-CVD (HDP-CVD) apparatus, the silicon nitride film 302 (second film) is formed (second step). FIG. 4B shows a HDP-CVD apparatus 1400. The HDP-CVD 1400 has a chamber 1401, an upper electrode 1402, and a lower electrode 1403. The upper electrode 1402 is disposed in the chamber 1401, the lower electrode 1403 also functions as a stage mounting a heater, and a semiconductor substrate 1404 can be placed on the lower electrode 1403. A high-frequency generator 1405 is connected to the upper electrode 1402, and a high-frequency generator 1406 is connected to the lower electrode 1403. A reaction gas is supplied from a supply port 1407.

In the HDP-CVD apparatus 1400 as described above, the film formation conditions are set as follows. First, by the high-frequency generator 1405, an electrical power of 2,500 to 3,500 W at an output frequency of 300 to 500 KHz is supplied to the upper electrode 1402. In addition, by the high-frequency generator 1406, an electrical power of 2,500 to 3,500 W at an output frequency of 13.56 MHz is supplied to the lower electrode 1403. In this embodiment, an electrical power of 3,200 W at a frequency of 400 KHz and an electrical power of 3,000 W are supplied to the upper electrode 1402 and the lower electrode 1403, respectively. In addition, into the HDP-CVD apparatus 1400, a mixed gas containing a silicon-containing gas, nitrogen, a nitrogen-containing gas, and an inert gas is supplied as a raw material gas. In this case, the silicon-containing gas indicates silane, TEOS, trimethylsilane, tetramethylsilane, or the like, the nitrogen-containing gas indicates ammonia or the like, and the inert gas indicates argon, helium, or the like. In this embodiment, a gas containing silane, nitrogen, ammonia, and argon is used. In addition, when the ratio of the inert gas is excessively increased, since a sputtering effect is excessively enhanced, the insulator 125 may be unfavorably removed in some cases. Hence, for example, the ratio of argon to silane in this step is preferably set to be low, such as in a range of 1.0 to 6.0. In this case, the ratio indicates the ratio in gas flow rate (flow rate ratio). Under the conditions as described above, the film 302 is formed. In this embodiment, the film 302 is formed thicker than the film 301.

In the process described above, the film formation in the first step and that in the second step are preferably performed as follows. The ratio of the high-frequency power for the lower electrode to that for the upper electrode of the HDP-CVD apparatus in the second step is higher than the ratio of the high-frequency power for the lower electrode to that for the upper electrode of the parallel plate type CVD apparatus in the first step. By the conditions as described above, the formation of the member in the opening can be made easier. In addition, in the second step, the silicon nitride film is preferably formed under the conditions in which the ratio of the sputtering effect to the film formation effect is higher than that in the first step. By the conditions as described above, the formation of the member in the opening can be made easier.

The film 301 formed under the conditions as described above has higher adhesion to the insulator 125 than that of the film 302. Accordingly, since the probability of peeling of the film 301 is low, the film 302 may also be formed without being peeled away. In addition, since the film 301 is provided between the film 302 and the insulator 125, the stress generated in the film 302 can be reduced, and hence a wafer can be suppressed from being deformed. That is, the film 301 having high adhesion to the insulator 125 can be formed in the first step, and in the second step, the film 302 can be formed so as to be easily filled in the opening. Hence, by the manufacturing method of this embodiment, while the peeling is suppressed, the wafer deformation can be suppressed.

Next, the stresses of the films 301 and 302 will be described. The stresses generated when films are uniformly formed on substrates by the respective manufacturing methods are as follows. The stress of a film formed by the same parallel plate type plasma CVD apparatus as that for the film 301 is −2.00×10⁹ dyne/cm², and the stress of a film formed by the same HDP-CVD apparatus as that for the film 302 is −1.00×10¹⁰ dyne/cm². In general, when the adhesion of the film to the insulator 125 is increased, the stress thereof apparently tends to increase as compared to that of the film to be filled in the opening. However, when the film 301 is formed by a parallel plate type plasma CVD apparatus which can reduce the stress of a film formed thereby as compared to that of a film formed by a HDP-CVD apparatus, generation of the wafer deformation can be suppressed.

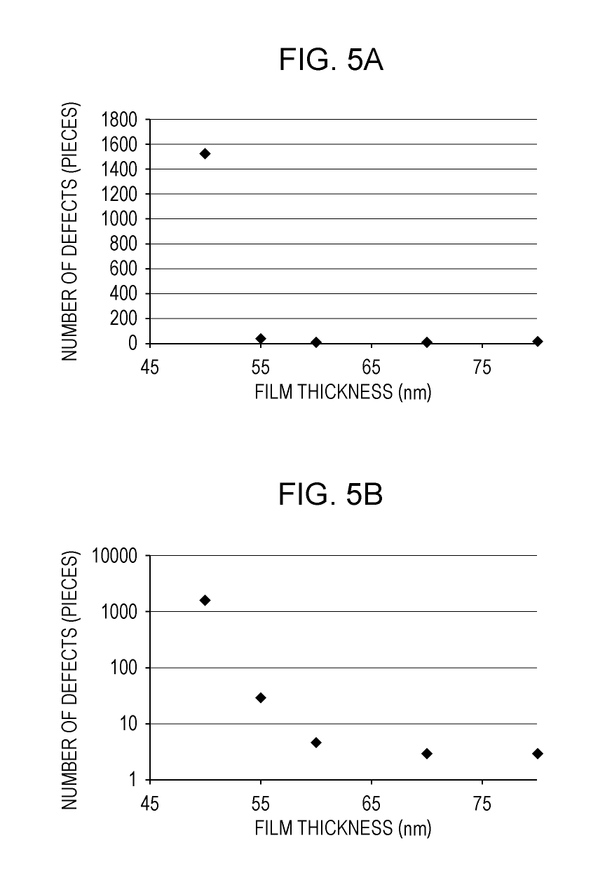

In addition, in this embodiment, the film 301 is formed to have a preferable thickness. The preferable thickness is 55 nm or more. In a graph shown in FIG. 5A, the horizontal axis represents the thickness (nm) of the film 301, and the vertical axis represents the number of defects (pieces) caused by peeling of the films 301 and 302. The number of defects indicates the number of defects which are generated in one wafer after the planarization treatment is performed on the films 301 and 302 formed in the opening of the insulator 125. In particular, the defects indicate a portion at which the film 301 and/or the film 302 is peeled away from the insulator 125, a portion at which the insulator 125 is partially peeled away together with the film 302, and the like.

In FIG. 5A, the number of defects is more than 1,000 when the film 301 has a thickness of 50 nm. This indicates that sufficient adhesion cannot be obtained when the thickness is 50 nm, and that in the following step (such as the planarization treatment), peeling occurs. FIG. 5A shows that when the film 301 has a thickness of 55 nm, the number of defects is decreased one-tenth or less. The reason for this is believed that since the adhesion between the film 301 and the insulator 125 is enhanced when the thickness of the film 301 is increased to 55 nm or more, the number of defects caused by the film which forms the light guide can be reduced. By the structure as described above, the yield can be improved. By the manufacturing method as described above, a light guide having a peeling resistance can be formed.

In addition, FIG. 5B is a graph in which the vertical axis of the graph in FIG. 5A is expressed by logarithm. The number of defects is approximately constant when the thickness of the film 301 is 50 nm or more. Hence, the thickness of the film 301 is preferably 50 nm or more. Furthermore, in consideration of manufacturing variation, the thickness is more preferably set to 70 nm or more.

In addition, the film 301 is preferably formed to have a thickness of 200 nm or less. As described above, since a film having higher adhesion has a higher stress, when the thickness thereof is increased, deformation may occur in some cases. In addition, the reason for this is that since the entrance of the opening 201 is blocked when the thickness of the film 301 is set to 200 nm or more, voids may be generated in some cases. Hence, the film 301 is preferably formed, for example, to have a thickness of 70 to 80 nm.

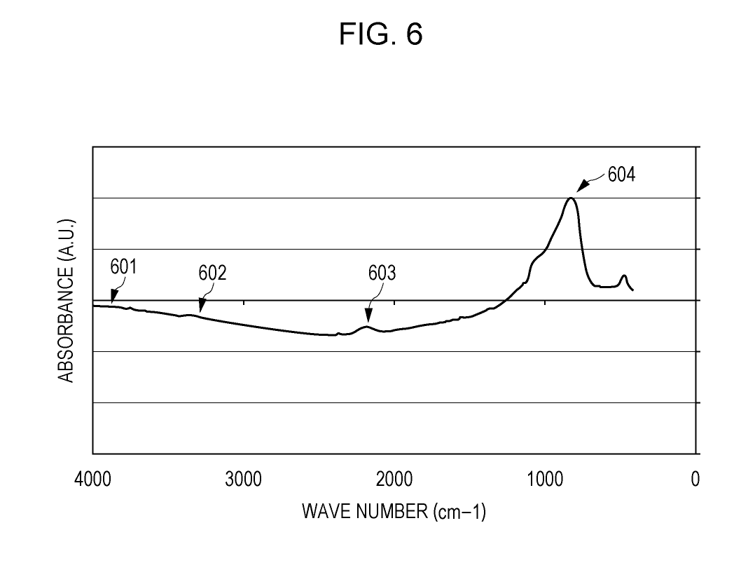

Next, the material of the film 301 will be described. FIG. 6 shows a graph showing the analytical result of the material obtained by a Fourier transform infrared spectroscopic method (hereinafter referred to as “FT-IR method”). The horizontal axis represents the wave number, and the vertical axis represents the absorbance (normalized). FIG. 6 shows a spectrum 601 of the film 301. The peak 602, the peak 603, and the peak 604 of the spectrum 601 indicate the presence of an N—H bond, a Si—H bond, and a Si—N bond, respectively. The peaks 602 and 603 are each smaller than the peak 604. Since the film 301 is formed of the material as described above, peeling of the films 301 and 302 can be suppressed.

In addition, between the first step and the second step, a step of forming a film (third film) may be further provided (third step). Heretofore, although the above structure is explained using the films 301 and 302 for convenience of description, the films may be integrally formed into one member as a final structure.

### Second Embodiment

In this embodiment, after the member 126 is formed, a planarization treatment is performed by a CMP method, so that the silicon nitride films 301 and 302 located on the upper surface of the insulator 125 are all removed. That is, in this embodiment, the upper surface of the insulator 125 is exposed, and this is a point different from that of the first embodiment. The rest of the structure of this embodiment is similar to that of the first embodiment.

According to the structure of this embodiment, since the thickness of the member 126 located on the insulator 125 shown in FIG. 1 is decreased, the distance from the microlens 144 to the photoelectric conversion element can be reduced. Hence, the sensitivity of the photoelectric conversion device can be improved.

### Third Embodiment

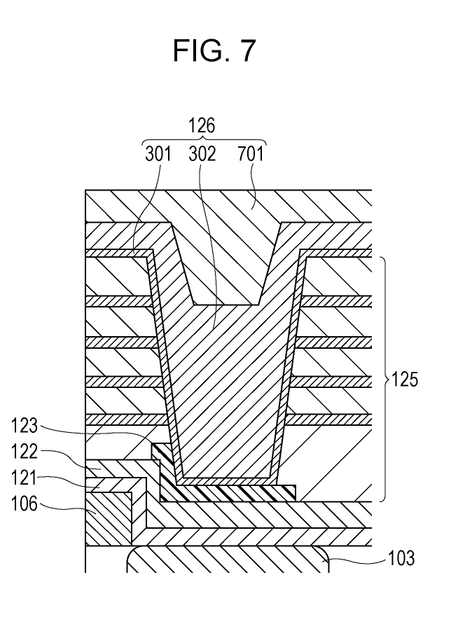

In this embodiment, the member 126 is formed of three films, and this is a point different from that of the first embodiment; however, the rest of the structure and the manufacturing method are similar to those of the first embodiment. FIG. 7 is a cross-sectional view of the member 126 corresponding to that shown in FIG. 3B. As shown in FIG. 7, the member 126 has the films 301 and 302 and a film 701.

In the manufacturing method of this embodiment, after the first and the second steps of the first embodiment are performed, a step of etching a part of the film 302 formed in the second step is performed. In addition, under the same conditions as those in the second step, a step of forming the film 701 (fourth film) is performed (fourth step). Since the etching step is performed between the above two steps as described above, after the films 301, 302, and 701, which form the member 126, are formed, the planarization can be easily performed. In addition, since the film 302 is partially removed, the stress thereof can be reduced, and generation of cracks and/or peeling of the high refractive index member can be suppressed. Incidentally, the three films may be integrally formed into one member.

### Fourth Embodiment

In this embodiment, a method for forming the film 302 (second step) is different from that of the first embodiment, and the rest of the structure and the manufacturing method of this embodiment are similar to those of the first embodiment. In this embodiment, helium is added besides nitrogen. Since helium is added, and the amount of nitrogen is decreased, the stress of the silicon nitride film can be reduced. In addition, in order to maintain the pressure inside the chamber constant, the amount of nitrogen which is decreased may be compensated for by the addition of helium. In addition, the pressure inside the chamber is preferably in a range of 3 to 10 m Torr and more preferably in a range of 6 to 9 m Torr. Since the pressure is set as described above, a silicon nitride film having a lower stress can be filled in the opening.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-267145, filed Dec. 25, 2013, which is hereby incorporated by reference herein in its entirety.

What is claimed is:

1. A method for manufacturing a photoelectric conversion device which includes:
a substrate including a photoelectric conversion element; and
a light guide which includes an insulator provided on the substrate, having an opening corresponding to the photoelectric conversion element, and containing silicon oxide and a member provided on the substrate, located in the opening, and containing silicon nitride, the method comprising:
forming a first silicon nitride film which forms the member in the opening by a parallel plate type plasma CVD apparatus; and
forming a second silicon nitride film which forms the member in the opening and on the first silicon nitride film by a high density plasma CVD apparatus,
wherein the first silicon nitride film has a thickness of 55 nm or more.

2. The method according to claim 1, wherein the first silicon nitride film has a thickness of 200 nm or less.

3. The method according to claim 1, wherein the first silicon nitride film has a thickness of 70 to 80 nm.

4. The method according to claim 1,
wherein the parallel plate type plasma CVD apparatus includes an upper electrode and a lower electrode,
the high density plasma CVD apparatus includes an upper electrode and a lower electrode and is operated under the conditions in which the ratio of a high frequency power for the lower electrode to that for the upper electrode is higher than the ratio of a high frequency power for the lower electrode to that for the upper electrode of the parallel plate type plasma CVD apparatus in the first step.

5. The method according to claim 4,
further comprising, between the forming the first silicon nitride film and the forming the second silicon nitride film, forming a third silicon nitride film which forms the member in the opening using a high density plasma CVD apparatus,
wherein the high density plasma CVD apparatus in the forming the third silicon nitride film includes an upper electrode and a lower electrode and is operated under the conditions in which the ratio of a high frequency power for the lower electrode to that for the upper electrode is between the ratio in the forming the first silicon nitride film and the ratio in the forming the second silicon nitride film.

6. The method according to claim 1,
wherein in the forming the second silicon nitride film, the silicon nitride film is formed at a higher ratio of a sputtering effect to a film formation effect than that in the forming the first silicon nitride film.

7. The method according to claim 1,
wherein in the forming the first silicon nitride film, a mixed gas containing a silicon-containing gas and a nitrogen-containing gas is supplied, and
in the forming the second silicon nitride film a mixed gas containing a silicon-containing gas, a nitrogen-containing gas, and an inert gas is supplied.

8. The method according to claim 1,
wherein in the forming the second silicon nitride film, the first silicon nitride film is formed on the insulator, and
in the forming the second silicon nitride film, the second silicon nitride film is formed on the insulator,
further comprising, after the forming the second silicon nitride film is performed, removing the first silicon nitride film and the second silicon nitride film so as to expose the upper surface of the insulator.

9. The method according to claim 1,
wherein in the forming the second silicon nitride film, the first silicon nitride film is formed on the insulator, and
in the forming the second silicon nitride film, the second silicon nitride film is formed on the insulator,
further comprising, after the forming the second silicon nitride film is performed, planarizing the second silicon nitride film on the insulator.

10. The method according to claim 1,
wherein in the forming the second silicon nitride film, the first silicon nitride film is formed on the insulator, and
in the forming the second silicon nitride film, the second silicon nitride film is formed on the insulator,
further comprising, after the forming the second silicon nitride film is performed, removing the second silicon nitride film so as to expose the upper surface of the first silicon nitride film.

11. The method according to claim 1,
further comprising, after the forming the second silicon nitride film is performed, forming a silicon oxide film.
